(19) United States
(12) Patent Application Publication
(10) Pub. No.: US 2021/0159249 A1
(43) Pub. Date: May 27, 2021

(54) PIXEL STRUCTURE FOR DISPLAY

(71) Applicant: WUHAN CHINA STAR OPTOELECTRONICS TECHNOLOGY CO., LTD., Wuhan, Hubei (CN)

(72) Inventors: Xin ZHANG, Wuhan, Hubei (CN); Guanghui LIU, Wuhan, Hubei (CN); Xindong MEI, Wuhan, Hubei (CN); Chao WANG, Wuhan, Hubei (CN)

(21) Appl. No.: 16/463,721

(22) PCT Filed: Nov. 5, 2018
(86) PCT No.: PCT/CN2018/113893

§ 371 Date: May 23, 2019

(30) Foreign Application Priority Data
Oct. 9, 2018 (CN) 201811173891.5

(51) Int. Cl. H01L 27/12

(52) U.S. Cl. CPC H01L 27/124

(57) ABSTRACT

A pixel structure for a display is provided. The pixel structure includes a substrate; a first metal layer disposed on the substrate, the first metal layer including at least one scanning line; an insulating layer disposed on the first metal layer, the insulating layer comprising a plurality of through holes; and a second metal layer disposed on the insulating layer, the second metal layer including at least one data line and at least one second metal segment, and the data line separated from the second metal segment; wherein the second metal segment is electrically connected in parallel with the scanning line via the plurality of through holes.

### FIELD OF INVENTION

The present invention relates to a field of display technologies, and more particularly, to a pixel structure for a display.

### BACKGROUND OF INVENTION

With innovation and development of display technology, the resolution of mainstream displays on the market is getting higher. Excellent image quality and visual experience of high-resolution displays are favored by consumers, so as to make them highly popular and more competitive on the market. However, as the resolution of the display is increased, impedance of a signal line in the display is also simultaneously increased and the design of the display is more challenging.

### SUMMARY OF INVENTION

The object of the present invention provides a pixel structure for a display, which realizes the electrical connection in parallel between the metal layer by optimizing the pixel design, such as another metal layer and corresponding connecting holes are added on the lateral or vertical metal layer (signal line layer), thereby reducing the impedance of the metal layer to solve the problem that high-resolution displays with high impedance.

In order to achieve the aforementioned objects of the present invention, the present invention provides a pixel structure for a display, comprising: a substrate; a first metal layer disposed on the substrate, the first metal layer comprising at least one scanning line and at least one first metal segment, and the scanning line separated from the first metal segment; an insulating layer disposed on the first metal layer, the insulating layer comprising a first through hole, a second through hole, a third through hole, and a fourth through hole; and a second metal layer disposed on the insulating layer, the second metal layer comprising at least one data line and at least one second metal segment, and the data line separated from the second metal segment; wherein the second metal segment is electrically connected in parallel with the scanning line via the first through hole and the second through hole, and the first metal segment is electrically connected in parallel with the data line via the third through hole and the fourth through hole.

In one embodiment of the present invention, the second metal segment is opposite to the scanning line, and the first metal segment is opposite to the data line.

In one embodiment of the present invention, the scanning line is insulated from the first metal segment, and the data line is insulated from the second metal segment.

In one embodiment of the present invention, the first metal layer comprises at least two scanning lines, and the first metal segment is disposed between the two adjacent scanning lines.

In one embodiment of the present invention, the second metal layer comprises at least two data lines, and the second metal segment is disposed between the two adjacent data lines.

In one embodiment of the present invention, two ends of the third through hole are electrically connected to the data line and the first metal segment, respectively, and two ends of the fourth through hole are electrically connected to the data line and the first metal segment, respectively.

In one embodiment of the present invention, two ends of the first through hole are electrically connected to the scanning line and the second metal segment, respectively, and two ends of the second through hole are electrically connected to the scanning line and the second metal segment, respectively.

The present invention further provides a pixel structure for a display, comprising: a substrate; a first metal layer disposed on the substrate, the first metal layer comprising at least one scanning line; an insulating layer disposed on the first metal layer, the insulating layer comprising a plurality of through holes; and a second metal layer disposed on the insulating layer, the second metal layer comprising at least one data line and at least one second metal segment, and the data line separated from the second metal segment; wherein the second metal segment is electrically connected in parallel with the scanning line via the plurality of through holes.

In one embodiment of the present invention, the plurality of through holes comprise a first through hole and a second through hole, two ends of the first through hole are electrically connected to the scanning line and the second metal segment, respectively, and two ends of the second through hole are electrically connected to the scanning line and the second metal segment, respectively.

In one embodiment of the present invention, the first metal layer comprises at least one first metal segment, the scanning line separated from the first metal segment, and the first metal segment is electrically connected in parallel with the data line via the plurality of through holes.

In one embodiment of the present invention, the plurality of through holes comprise a third through hole and a fourth through hole, two ends of the third through hole are electrically connected to the data line and the first metal segment, respectively, and two ends of the fourth through hole are electrically connected to the data line and the first metal segment, respectively.

In one embodiment of the present invention, the second metal segment is opposite to the scanning line.

In one embodiment of the present invention, the first metal segment is opposite to the data line.

The present invention further provides a pixel structure for a display, comprising: a substrate; a first metal layer disposed on the substrate, the first metal layer comprising at least one scanning line and at least one first metal segment, and the scanning line separated from the first metal segment; an insulating layer disposed on the first metal layer, the insulating layer comprising a plurality of through holes; and a second metal layer disposed on the insulating layer, the second metal layer comprising at least one data line; wherein the first metal segment is electrically connected in parallel with the data line via the plurality through holes.

In one embodiment of the present invention, the plurality of through holes comprise a third through hole and a fourth through hole, two ends of the third through hole are electrically connected to the data line and the first metal segment, respectively, and two ends of the fourth through hole are electrically connected to the data line and the first metal segment, respectively.

In one embodiment of the present invention, the first metal segment is opposite to the data line.

In one embodiment of the present invention, the scanning line is insulated from the first metal segment.

The beneficial effect: the impedance of the signal line can be reduced without changing the original process conditions. Therefore, there is no need to replace material of the existing metal layer, and the risk of the yield reduction can be avoided.

### DESCRIPTION OF DRAWINGS

In order to more clearly illustrate the technical solutions in the embodiments or the prior art, the following drawings, which are intended to be used in the description of the embodiments or the prior art, will be briefly described. It will be apparent that the drawings and the following description are only some embodiments of the present invention. Those of ordinary skill in the art may, without creative efforts, derive other drawings from these drawings.

FIG. 1 is a schematic structural view of a pixel structure of an existing display.

FIG. 1A is a cross-sectional view taken along line A-A of FIG. 1.

FIG. 2 is a schematic structural view of a pixel structure for a display of the present invention.

FIG. 3 is a cross-sectional view taken along line A-A of FIG. 2.

FIG. 4 is a cross-sectional view taken along line B-B of FIG. 2.

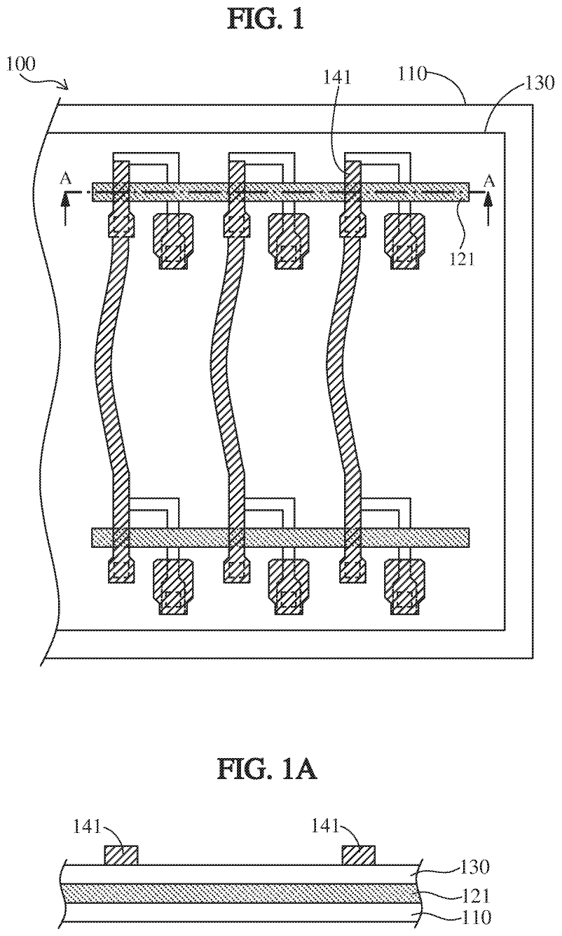

### DETAILED DESCRIPTION OF PREFERRED EMBODIMENTS

In the following detailed description of the preferred embodiments, reference is made to the accompanying drawings which form a part hereof, and in which is shown by way of illustration specific embodiments in which the invention may be practiced. In this regard, directional terminology, such as “top”, “bottom”, “front”, “back”, “left”, “right”, “inside”, “outside”, “side”, etc., is used with reference to the orientation of the figure(s) being described. As such, the directional terminology is used for purposes of illustration and is in no way limiting. Throughout this specification and in the drawings like parts will be referred to by the same reference numerals.

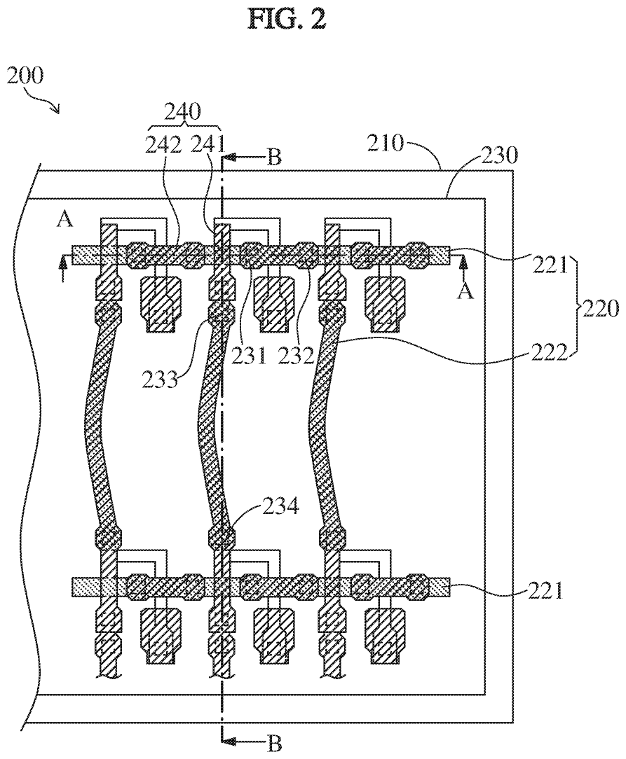

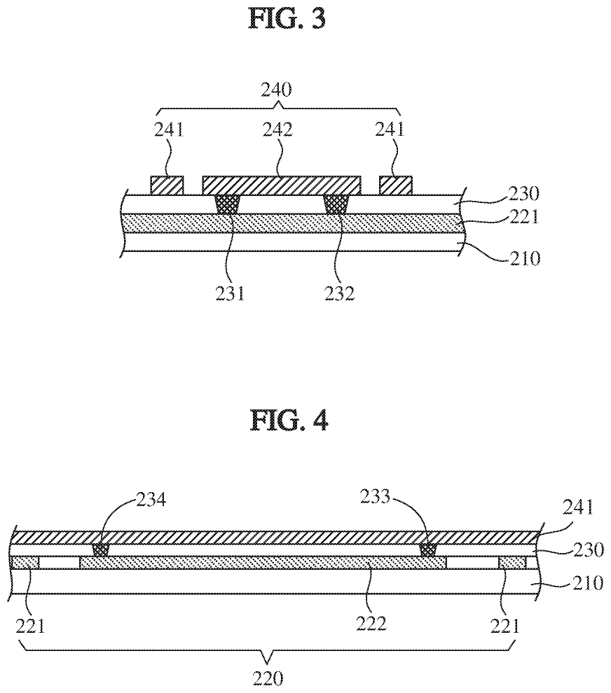

Please refer to FIG. 2 to FIG. 4. FIG. 2 is a schematic structural view of a pixel structure for a display of the present invention. FIG. 3 is a cross-sectional view taken along line A-A of FIG. 2. FIG. 4 is a cross-sectional view taken along line B-B of FIG. 2. As shown in FIG. 2, the present invention provides a pixel structure 200 for a display, the display includes a substrate 210, a first metal layer 220, an insulating layer 230, and a second metal layer 240.

The substrate 210 has light-transmitting properties, such as a glass substrate.

As shown in FIG. 3 and FIG. 4, the first metal layer 220 is disposed on the substrate 210. The first metal layer 220 includes at least one scanning line 221 and at least one first metal segment 222, and the scanning line 221 and the first metal segment 222 are separated from each other. That is, the scanning line 221 and the first metal segment 222 are insulated from each other, and there is no electrical connection between thereof. The first metal segment 222 may be disposed between two adjacent scanning lines 221. The first metal layer 220 may be deposited on the substrate 210 by deposition technique, and the first metal layer 220 may be patterned by a photolithography process to form the scanning line 221 and the first metal segment 222. The steps of photolithography process include photoresist coating, exposing, developing, etching, and stripping.

The insulating layer 230 is disposed on the first metal layer 220, and the insulating layer 230 includes a first through hole 231, a second through hole 232, a third through hole 233, and a fourth through hole 234. The insulating layer 230 is formed on the first metal layer 220 by a deposition technique, and the position of the first through hole 231, the second through hole 232, the third through hole 233, and the fourth through hole 234 are defined by a photolithography process and an etching technique. Subsequently, a conductive material, such as metal, is filled to form the first through hole 231, the second through hole 232, the third through hole 233, and the fourth through hole 234.

The second metal layer 240 is disposed on the insulating layer 230. The second metal layer 240 includes at least one data line 241 and at least one second metal segment 242, and the data line 241 and the second metal segment 242 are separated from each other. That is, the data line 241 and the second metal segment 242 are insulated from each other, and there is no electrical connection between thereof. The second metal segment 242 may be disposed between two adjacent data lines 241. The second metal layer 240 may be deposited on the insulating layer 230 by a deposition technique, and the second metal layer 240 may be patterned by a photolithography process to form the data line 241 and the second metal segment 242.

The second metal segment 242 is electrically connected in parallel with the scanning line 221 via the first through hole 231 and the second through hole 232, and the first metal segment 222 is electrically connected in parallel with the data line 241 via the third through hole 233 and the fourth through hole 234.

As shown in FIG. 3, the first through hole 231 and the second through hole 232 are disposed between the scanning line 221 and the second metal segment 242. Two ends of the first through hole 231 are electrically connected to the scanning line 221 and the second metal segment 242, respectively, and two ends of the second through hole 232 are electrically connected to the scanning line 221 and the second metal segment 242, respectively. In this way, the second metal segment 242 is electrically connected in parallel with the scanning line 221. Reducing the impedance of the scanning line 221 by electrical connections in parallel between the second metal segment 242 and the scanning line 221.

As shown in FIG. 4, the third through hole 233 and the fourth through hole 234 are disposed between the data line 241 and the first metal segment 222. Two ends of the third through hole 233 are electrically connected to the data line 241 and the first metal segment 222, respectively, and two ends of the fourth through hole 234 are electrically connected to the data line 241 and the first metal segment 222, respectively. In this way, the first metal segment 222 is electrically connected in parallel with the data line 242. Reducing the impedance of the data line 241 by electrical connections in parallel between the first metal segment 222 and the data line 241.

As shown in FIG. 3, the second metal segment 242 is opposite to the scanning line 221, and the second metal segment 242 is located above the scanning line 221. The pattern of the second metal segment 242 may also correspond to the pattern of the scanning line 221, that is, the pattern of the second metal segment 222 may overlap with a portion of the pattern of the scanning line 221, as shown in FIG. 2. Similarly, as shown in FIG. 4, the first metal segment 222 is opposite the data line 241, and the first metal segment 222 is located below the data line 241. The pattern of the first metal segment 222 may also correspond to the pattern of the data line 241, that is, the pattern of the first metal segment 222 may overlap with a portion of the pattern of the data line 241, as shown in FIG. 2.

According to different needs, the pixel structure for the display of the present invention can also have the following variations. For example, if only reducing the impedance of the scanning line 221 is needed, it is only to make the second metal layer 240 formed at least one data line 241 and at least one second metal segment 242, and to ensure the second metal segment 242 electrically connected in parallel with the scanning line 221 via the first through hole 231 and the second through hole 232, as shown in FIG. 3. Conversely, if only reducing the impedance of the data line 241 is needed, it is only to make the first metal layer 220 formed at least one scanning line 221 and at least one first metal segment 222, and to ensure the first metal segment 222 electrically connected in parallel with the data line 241 via the third through hole 233 and the fourth through hole 234.

According to the embodiments and variations described above, the present invention can reduce the impedance of the signal line (such as scanning lines or data lines) by optimizing the design of metal segments in the metal layers and the through holes corresponding to the metal segments.

The beneficial effect: the impedance of the signal line can be reduced without changing the original process conditions. Therefore, there is no need to replace material of the existing metal layer, and the risk of the yield reduction can be avoided.

In view of the above, although the present invention has been disclosed by way of preferred embodiments, the above preferred embodiments are not intended to limit the present invention, and one of ordinary skill in the art, without departing from the spirit and scope of the invention, the scope of protection of the present invention is defined by the scope of the claims.

What is claimed is:

1. A pixel structure for a display, comprising:
a substrate;
a first metal layer disposed on the substrate, the first metal layer comprising at least one scanning line and at least one first metal segment, and the scanning line separated from the first metal segment;
an insulating layer disposed on the first metal layer, the insulating layer comprising a first through hole, a second through hole, a third through hole, and a fourth through hole; and
a second metal layer disposed on the insulating layer, the second metal layer comprising at least one data line and at least one second metal segment, and the data line separated from the second metal segment;
wherein the second metal segment is electrically connected in parallel with the scanning line via the first through hole and the second through hole, and the first metal segment is electrically connected in parallel with the data line via the third through hole and the fourth through hole.

2. The pixel structure according to claim 1, wherein the second metal segment is opposite to the scanning line, and the first metal segment is opposite to the data line.

3. The pixel structure according to claim 1, wherein the scanning line is insulated from the first metal segment, and the data line is insulated from the second metal segment.

4. The pixel structure according to claim 1, wherein the first metal layer comprises at least two scanning lines, and the first metal segment is disposed between the two adjacent scanning lines.

5. The pixel structure according to claim 1, wherein the second metal layer comprises at least two data lines, and the second metal segment is disposed between the two adjacent data lines.

6. The pixel structure according to claim 4, wherein two ends of the third through hole are electrically connected to the data line and the first metal segment, respectively, and two ends of the fourth through hole are electrically connected to the data line and the first metal segment, respectively.

7. The pixel structure according to claim 5, wherein two ends of the first through hole are electrically connected to the scanning line and the second metal segment, respectively, and two ends of the second through hole are electrically connected to the scanning line and the second metal segment, respectively.

8. A pixel structure for a display, comprising:
a substrate;
a first metal layer disposed on the substrate, the first metal layer comprising at least one scanning line;
an insulating layer disposed on the first metal layer, the insulating layer comprising a plurality of through holes; and
a second metal layer disposed on the insulating layer, the second metal layer comprising at least one data line and at least one second metal segment, and the data line separated from the second metal segment;
wherein the second metal segment is electrically connected in parallel with the scanning line via the plurality of through holes.

9. The pixel structure according to claim 8, wherein the plurality of through holes comprise a first through hole and a second through hole, two ends of the first through hole are electrically connected to the scanning line and the second metal segment, respectively, and two ends of the second through hole are electrically connected to the scanning line and the second metal segment, respectively.

10. The pixel structure according to claim 8, wherein the first metal layer comprises at least one first metal segment, the scanning line separated from the first metal segment, and the first metal segment is electrically connected in parallel with the data line via the plurality of through holes.

11. The pixel structure of claim 10, wherein the plurality of through holes comprise a third through hole and a fourth through hole, two ends of the third through hole are electrically connected to the data line and the first metal segment, respectively, and two ends of the fourth through hole are electrically connected to the data line and the first metal segment, respectively.

12. The pixel structure according to claim 8, wherein the second metal segment is opposite to the scanning line.

13. The pixel structure according to claim 10, wherein the first metal segment is opposite to the data line.

14. A pixel structure fora display, comprising:
a substrate;
a first metal layer disposed on the substrate, the first metal layer comprising at least one scanning line and at least one first metal segment, and the scanning line separated from the first metal segment;
an insulating layer disposed on the first metal layer, the insulating layer comprising a plurality of through holes; and
a second metal layer disposed on the insulating layer, the second metal layer comprising at least one data line;
wherein the first metal segment is electrically connected in parallel with the data line via the plurality through holes.

15. The pixel structure according to claim 14, wherein the plurality of through holes comprise a third through hole and a fourth through hole, two ends of the third through hole are electrically connected to the data line and the first metal segment, respectively, and two ends of the fourth through hole are electrically connected to the data line and the first metal segment, respectively.

16. The pixel structure according to claim 14, wherein the first metal segment is opposite to the data line.

17. The pixel structure according to claim 14, wherein the scanning line is insulated from the first metal segment.
